(19) United States
(12) Patent Application Publication
(10) Pub. No.: US 2026/0206260 A1
(43) Pub. Date: Jul. 16, 2026

(54) SEMICONDUCTOR DEVICE AND MANUFACTURING METHOD OF THE SAME

(71) Applicant: Taiwan Semiconductor Manufacturing Company, Ltd., Hsinchu (TW)

(72) Inventors: Yi-Tse Hung, Hsinchu (TW); Chao-Ching Cheng, Hsinchu City (TW); Iuliana RADU, Hsinchu County (TW)

(73) Assignee: Taiwan Semiconductor Manufacturing Company, Ltd., Hsinchu (TW)

(21) Appl. No.: 19/021,216

(22) Filed: Jan. 15, 2025

(51) Int. Cl. H10D 30/67; H10D 30/00; H10D 30/01; H10D 30/43; H10D 62/10; H10D 62/83; H10D 64/27

(52) U.S. Cl. CPC H10D 30/6735; H10D 30/014; H10D 30/0191; H10D 30/43; H10D 30/502; H10D 30/6757; H10D 62/121; H10D 64/512; H10D 62/83

(57) ABSTRACT

A semiconductor device includes a transistor. The transistor includes a gate electrode layer, a channel, a gate dielectric layer, a first source/drain region and a second source/drain region and a dielectric pattern. The channel is disposed on the gate electrode layer. The gate dielectric layer is located between the channel and the gate electrode layer. The first source/drain region and the second source/drain region are disposed on the channel at opposite sides of the gate electrode layer. The dielectric pattern is disposed on the channel. The first source/drain region covers a first sidewall and a first surface of the dielectric pattern, and a second sidewall opposite to the first sidewall of the dielectric pattern is protruded from a sidewall of the first source/drain region.

### BACKGROUND

The integrated circuit (IC) industry has experienced a fast-paced growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component or line that can be formed using a fabrication process) has decreased. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1H are schematic cross-sectional views illustrating various stages of a method of forming a semiconductor device in accordance with some embodiments, and FIG. 1I is a top view of a semiconductor device in accordance with some embodiments.

FIG. 2A is a cross-sectional view of a semiconductor device in accordance with some alternative embodiments of the disclosure, and FIG. 2B is a top view of a semiconductor device in accordance with some embodiments.

FIG. 3A to FIG. 3G are schematic cross-sectional views illustrating various stages of a method of forming a semiconductor device in accordance with some embodiments, and FIG. 3H is a top view of a semiconductor device in accordance with some embodiments.

FIG. 4A is a cross-sectional view of a semiconductor device in accordance with some alternative embodiments of the disclosure, and FIG. 4B is a top view of a semiconductor device in accordance with some embodiments.

FIG. 5 is a cross-sectional view of a semiconductor device in accordance with some alternative embodiments of the disclosure.

FIG. 6A to FIG. 6I are schematic cross-sectional views illustrating various stages of a method of forming a semiconductor device in accordance with some embodiments.

FIG. 7 is a cross-sectional view of a semiconductor device in accordance with some alternative embodiments of the disclosure.

FIG. 8 is a cross-sectional view of a semiconductor device in accordance with some alternative embodiments of the disclosure.

FIG. 9 illustrates a method of forming a semiconductor device in accordance with some embodiments.

FIG. 10 illustrates a method of forming a semiconductor device in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

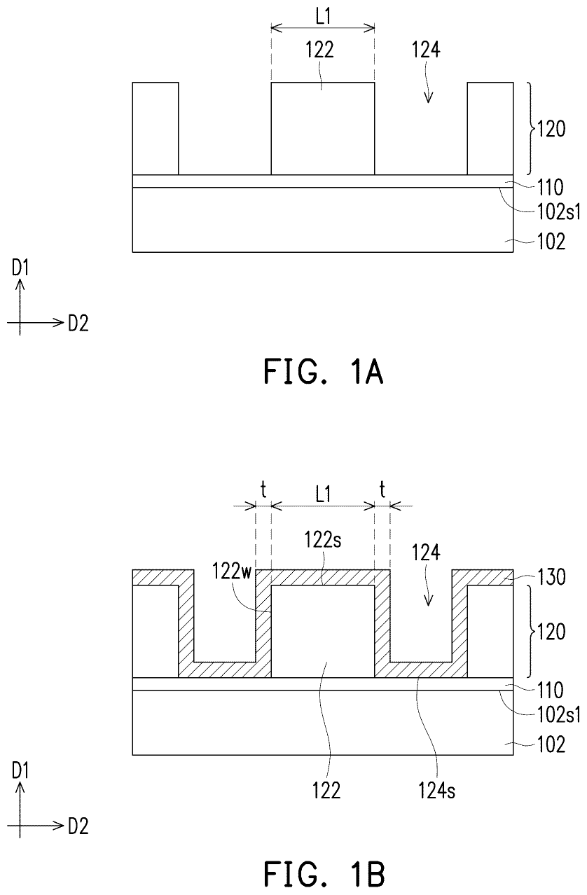

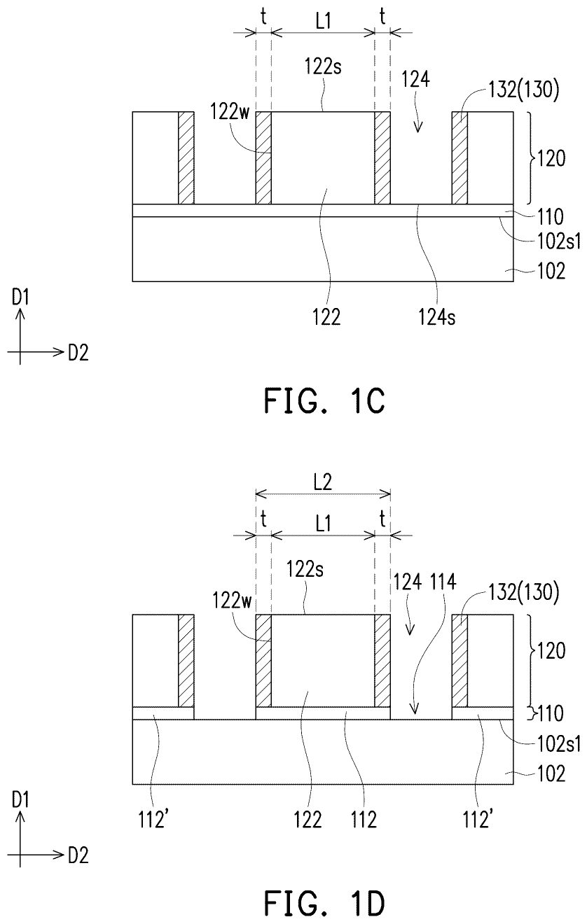

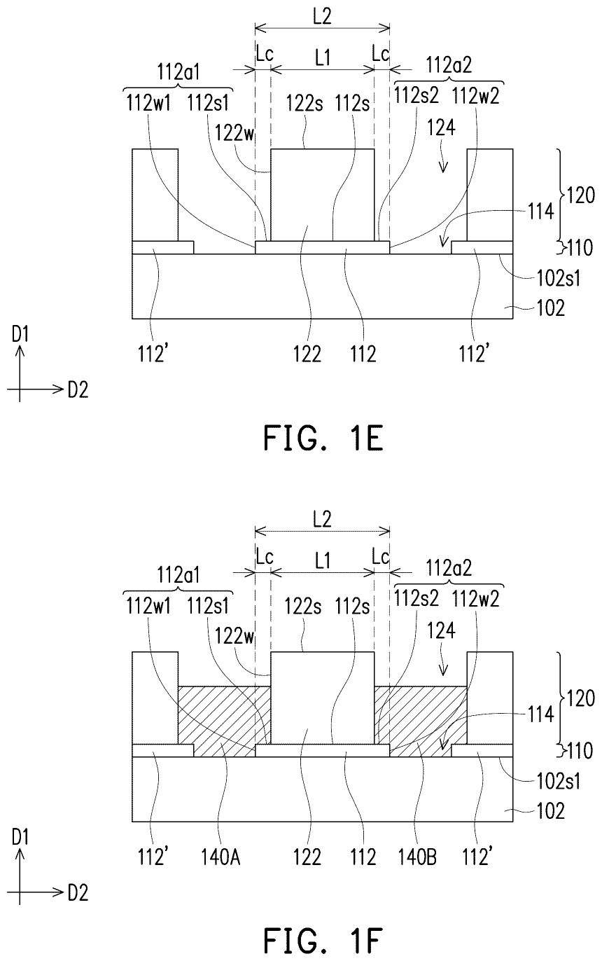

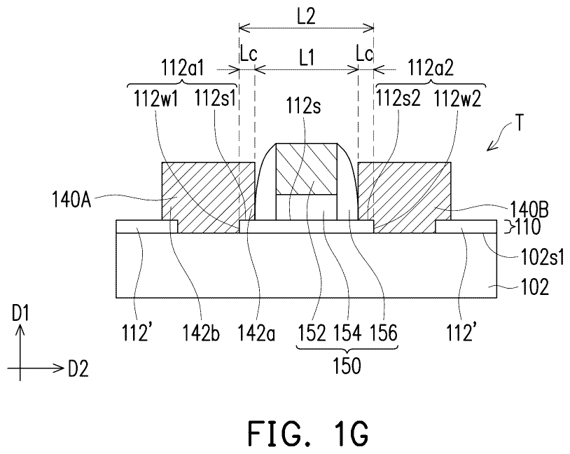

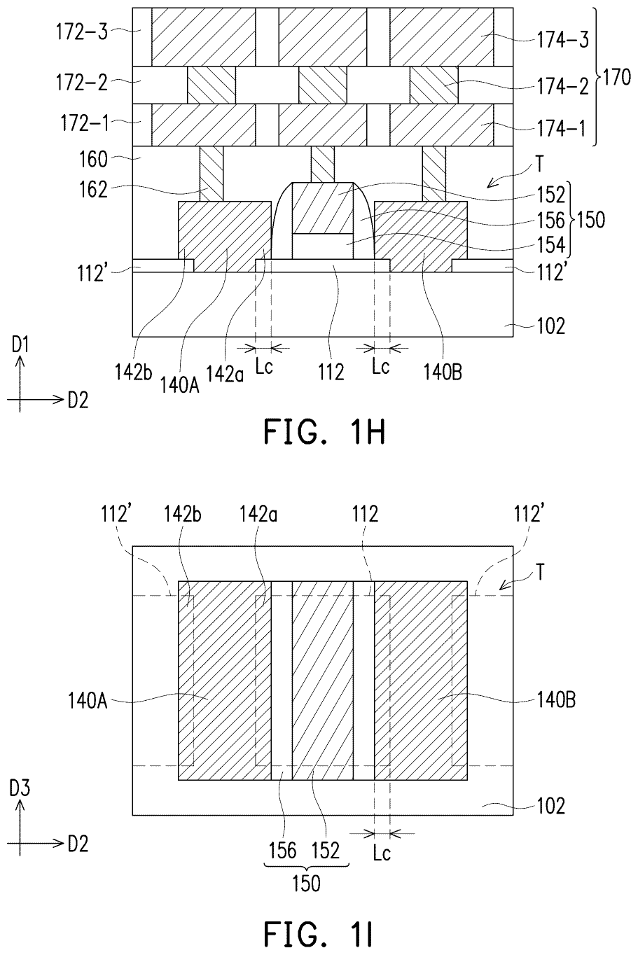

FIG. 1A to FIG. 1H are schematic cross-sectional views illustrating various stages of a method of forming a semiconductor device in accordance with some embodiments. FIG. 1I is a top view of a semiconductor device in accordance with some embodiments.

Referring to FIG. 1A, a material layer 110 is formed on a substrate 102 along a first direction D1. The first direction D1 is a vertical direction (e.g., z direction or height direction), for example. The material layer 110 may be disposed on a first surface (e.g., top surface) 102s1 of the substrate 102. In some embodiments, the substrate 102 includes a crystalline silicon substrate or a bulk silicon substrate (e.g., wafer). In some embodiments, the substrate 102 is made of a suitable elemental semiconductor (e.g., germanium), a suitable compound semiconductor (e.g., gallium arsenide, silicon carbide, indium arsenide, or indium phosphide), a suitable alloy semiconductor (e.g., silicon germanium carbide, gallium arsenic phosphide, or gallium indium phosphide), and the like. In some embodiments, the substrate 102 includes a semiconductor-on-insulator (SOI) substrate. The substrate 102 may include various doped regions (not individually shown) doped with p-type or n-type dopants. The doped regions may be configured for an n-type field effect transistor (FET), or alternatively, configured for a p-type FET. Other substrates, such as multilayered or gradient substrates, may also be used. In some embodiments, active devices (e.g., transistors, diodes, etc.), capacitors, resistors, the like, or a combination thereof, are formed in and/or on the substrate 102.

In some embodiments, the material layer 110 includes low-dimensional (e.g., two-dimensional (2D)) materials. The 2D material is usually few-layer thick and exists as stacks of strongly bonded layers with weak interlayer van der Waals attraction, allowing the layers to be mechanically or chemically exfoliated into individual, atomically thin layers. The 2D material may be the channel materials of ultra-thin/ultra-scaled body transistors. The 2D material may include 2D semiconductor material (e.g., transition metal dichalcogendies (TMDs), borophene, silicene, germanene, graphene, graphyne and/or black phosphorus), carbon nanotubes (CNTs), nanoribbon or the like. The TMDs may include molybdenum disulfide (MoS₂), tungsten disulfide (WS₂), tungsten diselenide (WSe₂) or the like. The 2D material is of the high electron mobility (μe) value, which is within a range of about 50-1000 cm²/V-sec or even higher, for example. It is understood that the bulk silicon, when cut to a small thickness (e.g., about 2 nm) comparable with a typical thickness of a 2D material layer, may have its mobility degraded drastically. Thus, the 2D material provides an ideal geometry for an excellent electrostatic control. The 2D material may be used for applying in both front-end-of-line (FEOL) and back-end-of-line (BEOL) devices.

In some embodiments, the material layer 110 includes the 2D material and is subsequently formed into a channel of a FET. For example, the material layer 110 includes carbon nanotubes for n-FET or TMDs for p-FET. In some embodiments, the material layer 110 includes one or more layers and has a thickness within the range of about 0.3-100 nm. The material layer 110 may be formed by a deposition process such as atomic layer deposition (ALD) process or any suitable process. For example, an atomic layer of the material layer 110 has a thickness within the range of about 0.3-1 nm, and the material layer 110 ranges from 1 monolayer to 20 monolayers. However, the disclosure is not limited thereto. Depending on the requirements, the material layer 110 may include other suitable materials such as semiconductor material (e.g., silicon), oxide semiconductor material (e.g., IZO, IGZO, ZnO, InO or GaO), conductive material, insulating material, a combination thereof or the like.

Then, a patterned layer 120 is formed on the material layer 110. The patterned layer 120 includes a plurality of patterns 122 and a plurality of openings 124. The patterns 122 cover portions of the material layer 110, the openings 124 expose portions of the material layer 110, and the pattern 122 is disposed between the openings 124. The pattern 122 may have a length L1 corresponding to a length (Lg) of the gate structure to be formed along a second direction D2. The second direction D2 is substantially perpendicular to the first direction D1. For example, the second direction D2 is a horizontal direction (e.g., x direction or length direction). The patterned layer 220 may include a photoresist material, an oxide material such as semiconductor oxide (e.g., SiO₂) or other suitable materials. In some embodiments, the patterned layer 120 is a patterned photoresist layer.

Referring to FIG. 1B, a lining layer 130 is formed on the patterned layer 120. The lining layer 130 may be conformally formed on exposed surfaces of the patterned layer 120. For example, the lining layer 130 is conformally and continuously formed on top surfaces 122s and opposite sidewalls 122w of the patterns 122 and bottom surfaces 124s of the openings 124. In some embodiments, the material layer 110, the patterned layer 120 and the lining layer 130 may have different materials (or compositions) that may provide for different etch selectivity therebetween. The lining layer 130 may include an oxide material such as semiconductor oxide (e.g., SiO₂), a high-k dielectric material (e.g., Al₂O₃, HfO₂), metal oxide such as transition metal oxide (e.g., WOₓ, MoOₓ, TiOₓ) or the like. The lining layer 130 is formed by an atomic layer deposition (ALD) process or the like, for example. A cycle number of the ALD process for forming the lining layer 130 may be in a range of 10 to 70. The lining layer 130 may have a thickness t on the sidewall 122w of the pattern 122 of the patterned layer 120 along the second direction D2, and the lining layer 130 may also have a thickness substantially equal to the thickness t on the top surface 122s of the pattern 122 and on the bottom surface 124s of the opening 124 along the first direction D1. The thickness t of the lining layer 130 may be smaller than 10 nm.

Referring to FIG. 1C, the lining layer 130 on the bottom surfaces 124s of the openings 124 is removed, to expose the material layer 110. The lining layer 130 may be partially removed by an anisotropic etch process such as anisotropic reactive ion etch (RIE) process. In some embodiments, during the removal of the lining layer 130 on the bottom surfaces 124s of the openings 124, the lining layer 130 on the top surfaces 122s of the patterns 122 may be also removed while the lining layer 130 on the sidewalls 122w of the patterns 122 are not removed or remained substantially intact. In other words, the sidewalls 122w of the patterns 122 are still covered by the lining layer 130 (e.g., lining patterns 132 of the lining layer 130). As shown in FIG. 1C, after the lining layer 130 is partially removed, portions of the material layer 110 are exposed by the openings 124.

Referring to FIG. 1D, the material layer 110 exposed by the openings 124 is removed, to form a pattern 112, 112′ below the pattern 122 and a plurality of openings 114 below the openings 124. For example, by using the patterned layer 120 and the remained lining layer 130 (e.g., lining patterns 132) as a mask, the material layer 110 of FIG. 1C is patterned. The material layer 110 may be partially removed by a dry etch process or a wet etch process. For example, the material layer 110 is partially removed by an anisotropic etch process such as anisotropic reactive ion etch (RIE) process. In some embodiments, the etch process for the removal of the material layer 110 (e.g., as shown in FIG. 1D) is performed separately from the etch process for the removal of the lining layer 130 (e.g., as shown in FIG. 1C). However, the disclosure is not limited thereto. In alternative embodiments, the material layer 110 and the lining layer 130 are partially removed by the same etch process.

After partial removal, the material layer 110 includes a plurality of patterns 112, 112′ corresponding to the patterns 122 of the patterned layer 120 and a plurality of openings 114 corresponding to the openings 124 of the patterned layer 120. The pattern 112 is disposed between the openings 114, and the opening 114 exposes a portion of the substrate 102, for example. The pattern 112 may be disposed below and covered by the pattern 122 and the lining layer 130 on the sidewalls 122w of the pattern 122, and the opening 114 may be disposed below and communicated with the opening 124. In some embodiments, sidewalls of the pattern 112 are substantially flush with outer sidewalls of the lining patterns 132 on the pattern 122. Accordingly, the pattern 112 may have a length L2 substantially equal to a total length of the pattern 122 and the lining patterns 132 on opposite sidewalls 122w of the pattern 122, that is, the length L2 of the pattern 112 is substantially equal to L1 plus 2t (i.e., L1+2t).

Referring to FIG. 1E, the lining layer 130 (e.g., lining patterns 132) on the opposite sidewalls 122w of the pattern 122 is removed, to expose opposite sides 112a1, 112a2 of the pattern 112. The lining layer 130 may be removed by a wet etch process or a dry etch process. For example, the lining layer 130 is entirely removed by a wet etch process. After removal of the lining layer 130, the opposite sides 112a1, 112a2 of the pattern 112 are exposed. The sides 112a1, 112a2 (e.g., left and right sides in FIG. 1E) are disposed opposite to each other along the second direction D2. The first side 112a1 includes a first sidewall 112w1 of the channel 112 and a first portion 112s1 of a surface (e.g., top surface) 112s of the channel 112. The second side 112a2 includes a second sidewall 112w2 of the channel 112 and a second portion 112s2 of the surface (e.g., top surface) 112s of the channel 112. The first portion 112s1 and the second portion 112s2 are also referred to as surfaces. The pattern 112 extends beyond the pattern 122 by a length Lc, and the length L2 of the pattern 112 is substantially equal to L1 plus 2Lc (i.e., L1+2Lc). The length Lc is substantially equal to the thickness t, for example. In some embodiments, the pattern 112 serves as a channel 112, and is also referred to as channel layer or channel region, and the patterns 112′ serve as a channel or a dummy pattern. The sides 112a1, 112a2 are also referred to as end portions, edge portions or the like.

Referring to FIG. 1F, patterns 140A, 140B are formed in the openings 114, 124. For example, a material such as a conductive material is formed in the openings 114, 124, to form the pattern 140A, 140B. The conductive material includes cobalt, tungsten, copper, titanium, tantalum, aluminum, zirconium, hafnium, a combination thereof, or other suitable metallic materials, and is formed through CVD, ALD, plating, or other suitable deposition techniques. However, the disclosure is not limited thereto. Depending on the requirements, the patterns 140A, 140B may include other suitable materials such as insulating material or the like. Then, the patterned layer 120 is removed by a removal process such as a stripping process, an etch process or the like.

In some embodiments, the patterns 140A, 140B serves as source/drain contacts 140A, 140B. In some embodiments, the source/drain contacts 140A, 140B are disposed on and cover the opposite sides 112a1, 112a2 (e.g., left and right sides). As shown in FIG. 1F, the source/drain contacts 140A covers the portion 112s1 of the surface (e.g., top surface) 112s of the channel 112 and the sidewall 112w1 of the channel 112, and the source/drain contacts 140B covers the portion 112s2 of the surface (e.g., top surface) 112s of the channel 112 and the sidewall 112w2 of the channel 112. For example, as shown FIG. 1I, in a top view, a projection of the source/drain contact 140A onto the substrate 102 is partially overlapped with a projection of the channel 112 onto the substrate 102, and similarly, a projection of the source/drain contact 140B onto the substrate 102 is partially overlapped with a projection of the channel 112 onto the substrate 102. It is noted that although widths of the source/drain contacts 140A, 140B, the channel 122 and the gate structure 150 in a third direction D3 are illustrated as being equal, the widths of the source/drain contacts 140A, 140B, the channel 122 and the gate structure 150 may be different. The third direction D3 is substantially perpendicular to the first direction D1 and the second direction D2. For example, the third direction D3 is a horizontal direction (e.g., y direction or width direction).

The surface 112s may be disposed between the first sidewall 112w1 and the second sidewall 112w2. For example, the first portion 112s1 of the surface 112s is continuous with the first sidewall 112w1, and the second portion 112s2 of the surface 112s is continuous with the second sidewall 112w2. In other words, the source/drain contacts 140A continuously covers the first sidewall 112w1 and the first portion 112s1 of the channel 112, and the source/drain contacts 140B covers the second sidewall 112w2 and the second portion 112s2 of the channel 112. The source/drain contacts 140A is in direct contact with the first sidewall 112w1 and the first portion 112s1 of the channel 112, and the source/drain contacts 140B is in direct contact with the second sidewall 112w2 and the second portion 112s2 of the channel 112, for example. In alternative embodiments, the sidewalls 112w1, 112w2 are also referred to as side surfaces or the like.

Referring to FIG. 1G, a gate structure 150 is formed on a side of the channel 112 along the first direction D1. For example, the gate structure 150 is disposed between the source/drain contact 140A and the source/drain contact 140B on the surface (e.g., top surface) 112s of the channel 112. The channel 112 may be disposed between the substrate 102 and the gate structure 150. In some embodiments, the gate structure 150, the channel 112, the source/drain contact 140A and the source/drain contact 140B are disposed on the same side (e.g., first surface 102s1) of the substrate 102 along the first direction D1. The gate structure 150 includes a gate electrode layer 152, a gate dielectric layer 154 between the gate electrode layer 152 and the channel 112 and a spacer 156 surrounding the gate electrode layer 152. Accordingly, a transistor T is formed on the substrate 102. The transistor T is a planar transistor such as a top gate transistor. The gate structure 150 may have a gate length substantially equal to the length L1 of the pattern 122 as shown in FIG. 1A to FIG. 1E. In some embodiments, a material of the gate electrode layer 152 includes cupper (Cu), aluminum (Al), titanium (Ti), tungsten (W), tantalum (Ta), nitride thereof, other low resistance material, the like, a combination thereof, and/or alloys thereof. A material of the gate dielectric layer 154 may include a dielectric material, such as silicon oxide, silicon nitride, silicon carbide, silicon oxynitride, silicon carbonitride, silicon carbide oxynitride, a high-k dielectric material (e.g., Al₂O₃, HfO₂), an insulating-like 2D material (such as h-BN), or a combination thereof. A thickness of the gate dielectric layer 154 along the first direction D1 is in a range of 0.5 to 15 nm, for example. A material of the spacer 156 includes silicon nitride or the like.

Referring to FIG. 1H, a passivation layer 160 and conductive patterns 162 are formed over the transistor T. A material of the passivation layer 160 may include a dielectric material, such as silicon oxide, silicon nitride, silicon carbide, silicon oxynitride, silicon carbonitride, silicon carbide oxynitride, a high-k dielectric material (e.g., Al₂O₃, HfO₂), an insulating-like 2D material (such as h-BN), or a combination thereof. The conductive patterns 162 are electrically connected to the gate structure 150, the source/drain contact 140A and the source/drain contact 140B respectively. The conductive patterns 162 may be conductive contacts, conductive vias or conductive lines. A material of conductive patterns 162 includes cobalt, tungsten, copper, titanium, tantalum, aluminum, zirconium, hafnium, a combination thereof, or other suitable metallic materials, for example.

Then, an interconnect structure 170 may be formed over the passivation layer 160 to electrically connect the transistor T through the conductive patterns 162. For example, the interconnect structure 170 includes a plurality of dielectric layers 172-1, 172-2, 172-3 stacked along the first direction D1 and a plurality of conductive patterns 174-1, 174-2, 174-3 in the dielectric layers 172-1, 172-2, 172-3. The conductive patterns 174-1, 174-2, 174-3 may be conductive vias or conductive lines. The conductive patterns 162 are disposed between the conductive patterns 174-1 and the gate structure 150 and between the conductive patterns 174-1 and the source/drain contacts 140A and 140B. In some embodiments, a material of the dielectric layer 172-1, 172-2, 172-3 include a dielectric material such as silicon oxide, silicon nitride, silicon carbide, silicon oxynitride, silicon carbonitride, silicon carbide oxynitride or a high-k dielectric material (e.g., Al₂O₃, HfO₂), an organic material such as polyimide, epoxy resin, acrylic resin, phenol resin, benzocyclobutene (BCB), polybenzooxazole (PBO), the like, or a combination thereof. A material of conductive patterns 174-1, 174-2, 174-3 includes cobalt, tungsten, copper, titanium, tantalum, aluminum, zirconium, hafnium, a combination thereof, or other suitable metallic materials, for example.

In some embodiments, the source/drain contact 140A, 140B overlaps with and contacts the channel 112 therebelow by a length Lc, and thus the length Lc is also referred to as a contact length. The contact length Lc is substantially equal to the thickness t of the lining layer 130 on the pattern 122 as shown in FIG. 1B to FIG. 1D. In other words, the contact length Lc is predetermined by the thickness t of the lining layer 130, which is formed by applying ALD process. Thus, the source/drain contact 140A, 140B may have an atomically precise control of the contact length Lc. The contact length Lc formed by applying the ALD process is smaller than the contact length formed by using the lithography process (e.g., applying an e-beam lithography alignment accuracy and photoresist resolution), and thus the contact length Lc may be also referred to as ultra-scaled contact length. In some embodiments, by a hybrid contact (e.g., top surface contact and sidewall contact) between the source/drain contact 140A, 140B and the channel 112, the current injection may be improved. Furthermore, a fermi-level pinning issue of contact between the source/drain contact 140A, 140B and the low dimensional material (e.g., 2D material of the channel 112) may be reduced.

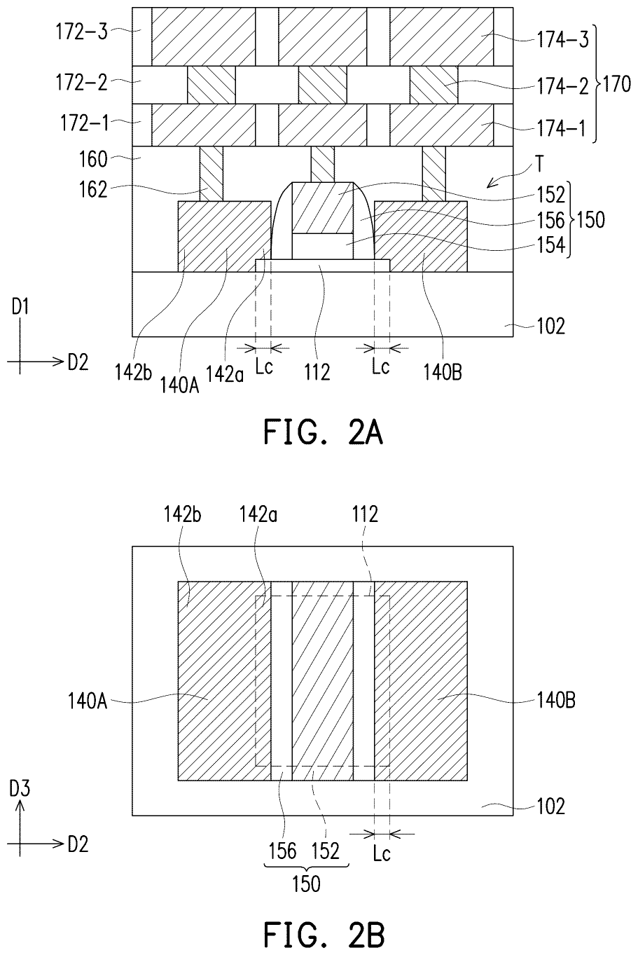

In some embodiments, a first side 142a of the source/drain contact 140A, 140B is disposed on and covers the channel 112 therebelow, and a second side 142b of the source/drain contact 140A, 140B is disposed on and covers the pattern 112′ therebelow. Thus, the source/drain contact 140A, 140B is T-shaped. In such embodiments, the source/drain contact 140A, 140B penetrates through the material layer 110 (including the channel 112 and the pattern 112'). The pattern 112′ may serve as a channel layer of another transistor (not shown) immediately adjacent to a transistor T to be formed or a dummy pattern. However, the disclosure is not limited thereto. The source/drain contact 140A, 140B may include other shape. In alternative embodiments in which the pattern 112′ is removed before forming the source/drain contact 140A or 140B, as shown in FIG. 2A and FIG. 2B, only one side 142a of the source/drain contact 140A or 140B covers the channel 112 between the source/drain contacts 140A and 140B.

It is noted that by using the processes described in FIG. 1A to FIG. 1F, a hybrid contact (e.g., top surface contact and sidewall contact) between the pattern 140 and the pattern 112 is formed, and the processes may be applied in any suitable semiconductor device with the need of a reduced contact length (e.g., ultra-scaled contact length) and/or an improvement of the contact therebetween.

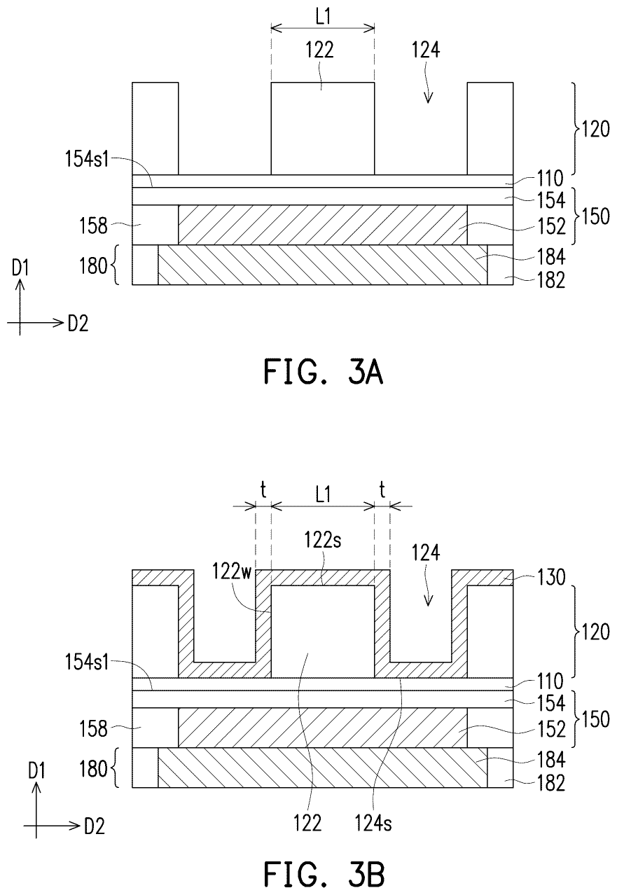

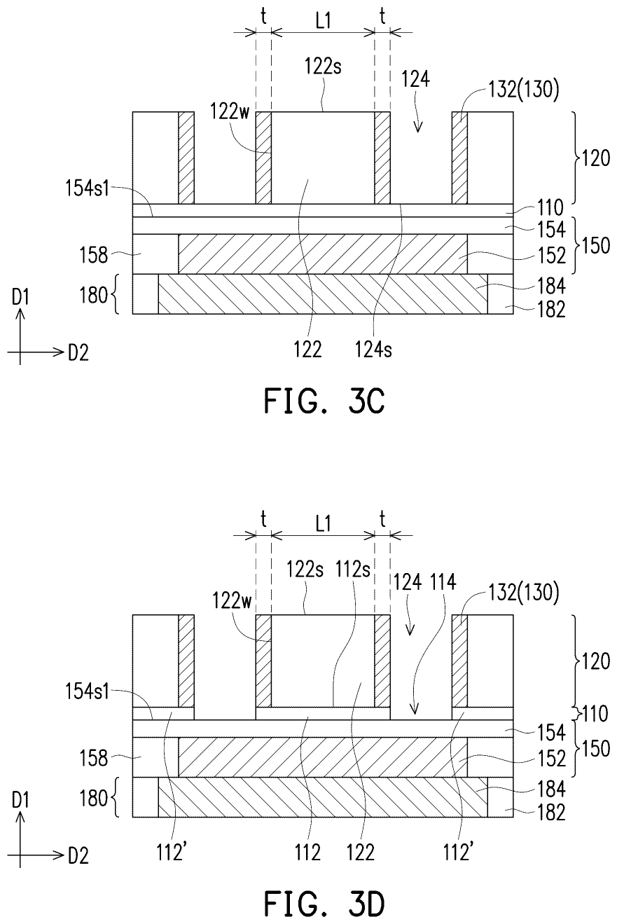

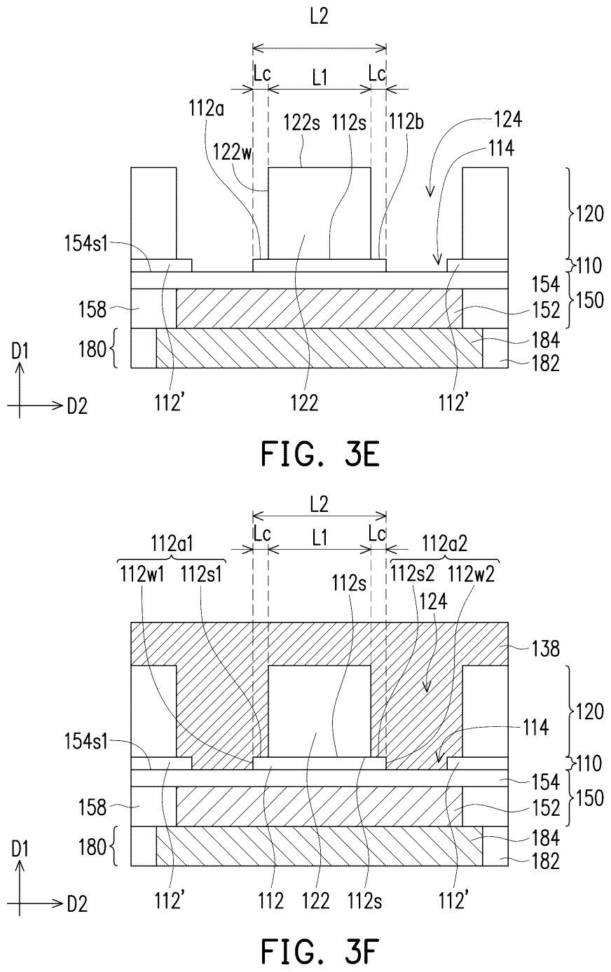

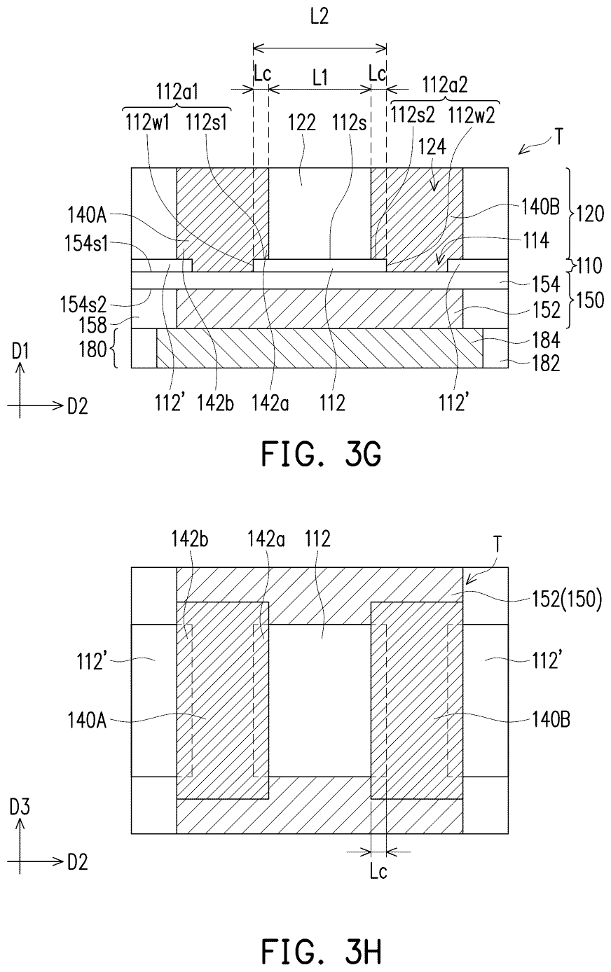

FIG. 3A to FIG. 3G are schematic cross-sectional views illustrating various stages of a method of forming a semiconductor device in accordance with some embodiments. FIG. 3H is a top view of a semiconductor device in accordance with some embodiments.

Referring to FIG. 3A, a material layer 110 is formed on a gate structure 150 along a first direction D1. In some embodiments, the gate structure 150 includes a gate electrode layer 152 and a gate dielectric layer 154. For example, the gate electrode layer 152 is formed in an isolation layer 158 on an underlying structure 180, and the gate dielectric layer 154 is formed on the gate electrode layer 152. The material layer 110 may be formed on a surface (e.g., top surface) 154s1 of the gate dielectric layer 154. In some embodiments, the underlying structure 180 is an interconnect structure, and includes at least one dielectric layer 182 and at least one conductive pattern 184 in the dielectric layer 182. In some embodiments, the dielectric layer 182 and conductive pattern 184 are similar to the dielectric layer 172-1, 172-2, 172-3 and the conductive pattern 174-1, 174-2, 174-3. Then, a patterned layer 120 is formed on the material layer 110. The patterned layer 120 includes a plurality of patterns 122 and a plurality of openings 124. The pattern 122 has a length L1. The pattern 122 may have a length L1 along a second direction D2. In some embodiments, the material and forming method of the material layer 110 and the patterned layer 120 are similar to those described in FIG. 1A, and the material of the gate electrode layer 152 and the gate dielectric layer 154 are similar to those described in FIG. 1G, so the detailed description thereof is omitted herein. The isolation layer 158 may includes a dielectric material, such as silicon oxide, silicon nitride, silicon carbide, silicon oxynitride, silicon carbonitride, silicon carbide oxynitride, SOG, PSG, BPSG, FSG, carbon doped silicon oxide (e.g., SiCOH), polyimide, a high-k dielectric material, an insulating-like low-dimension material or a combination thereof.

Referring to FIG. 3B, a lining layer 130 is formed on the patterned layer 120. In some embodiments, the material and forming method of the lining layer 130 are similar to those described in FIG. 1B, so the detailed description thereof is omitted herein. For example, the lining layer 130 is conformally and continuously formed on top surfaces 122s and opposite sidewalls 122w of the patterns 122 and bottom surfaces 124s of the openings 124. The lining layer 130 may have a thickness t on the sidewall 122w of the pattern 122 of the patterned layer 120 along the second direction D2, and the lining layer 130 may also have a thickness substantially equal to the thickness t on the top surface 122s of the pattern 122 and on the bottom surface 124s of the opening 124 along the first direction D1.

Referring to FIG. 3C, the lining layer 130 on the bottom surfaces 124s of the openings 124 is removed, to expose the material layer 110. In some embodiments, the partial removal of the lining layer 130 is similar to that described in FIG. 1C, so the detailed description thereof is omitted herein. As shown in FIG. 3C, after the lining layer 130 is partially removed, portions of the material layer 110 are exposed by the openings 124, and the sidewalls 122w of the patterns 122 are still covered by the lining layer 130 (e.g., lining patterns 132 of the lining layer 130).

Referring to FIG. 3D, the material layer 110 exposed by the openings 124 is removed, to form a pattern 112, 112′ below the pattern 122 and a plurality of openings 114 below the openings 124. In some embodiments, the partial removal of the material layer 110 is similar to that described in FIG. 1D, so the detailed description thereof is omitted herein. After partial removal, the material layer 110 includes a plurality of patterns 112, 112′ corresponding to the patterns 122 of the patterned layer 120 and a plurality of openings 114 corresponding to the openings 124 of the patterned layer 120. In some embodiments, the pattern 112 may have a length L2 substantially equal to a total length of the pattern 122 and the lining patterns 132 on opposite sidewalls 122w of the pattern 122, that is, the length L2 of the pattern 112 is substantially equal to L1 plus 2t (i.e., L1+2t).

Referring to FIG. 3E, the lining layer 130 (e.g., lining patterns 132) on the opposite sidewalls 122w of the pattern 122 is removed, to expose opposite sides 112a1, 112a2 of the pattern 112. In some embodiments, the removal of the remained lining layer 130 is similar to that described in FIG. 1E, so the detailed description thereof is omitted herein. After removal of the lining layer 130, the opposite sides 112a1, 112a2 of the pattern 112 are exposed. The sides 112a1, 112a2 (e.g., left and right sides in FIG. 3E) are disposed opposite to each other along the second direction D2. The first side 112a1 includes a first sidewall 112w1 of the channel 112 and a first portion 112s1 of a surface (e.g., top surface) 112s of the channel 112. The second side 112a2 includes a second sidewall 112w2 of the channel 112 and a second portion 112s2 of the surface (e.g., top surface) 112s of the channel 112. The surface 112s may be disposed between the first sidewall 112w1 and the second sidewall 112w2. The second sidewall 112w2 is opposite to the first sidewall 112w1 along the second direction D2, and the first portion 112s1 is disposed opposite to the second portion 112s2 along the second direction D2, for example. The first portion 112s1 and the second portion 112s2 are also referred to as surfaces. The pattern 112 extends beyond the pattern 122 by a length Lc, and the length L2 of the pattern 112 is substantially equal to L1 plus 2Lc (i.e., L1+2Lc). The length Lc is substantially equal to the thickness t, for example. In some embodiments, the pattern 112 serves as a channel 112, and is also referred to as channel layer or channel region, and the patterns 112′ serve as a channel or a dummy pattern.

Referring to FIG. 3F, a conductive material 138 is formed in the openings 114, 124 and covers the patterned layer 120. In some embodiments, the conductive material 138 includes cobalt, tungsten, copper, titanium, tantalum, aluminum, zirconium, hafnium, a combination thereof, or other suitable metallic materials. In some embodiments, the conductive material 138 is formed through CVD, ALD, plating, or other suitable deposition techniques.

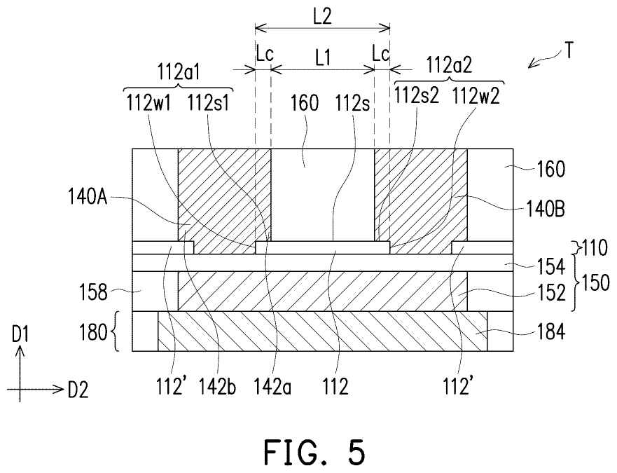

Referring to FIG. 3G, a portion of the conductive material 138 is removed, to form patterns 140A, 140B in the openings 114, 124. For example, the conductive material 138 outside the openings 114, 124 is removed by a planarization process such as CMP process. In some embodiments, after the formation of the patterns 140A, 140B, the patterned layer 120 serves as passivation layer without being removed. However, the disclosure is not limited thereto. In alternative embodiments, as shown in FIG. 5, the patterned layer 120 is removed after the formation of the patterns 140A, 140B, and a passivation layer 160 is additionally formed to passivate the patterns 140A, 140B. In some embodiments, the pattern 112 serves as a channel, and the patterns 140A, 140B serves as source/drain contacts 140A, 140B. Accordingly, a transistor T is formed on the underlying structure 180. The transistor T is a planar transistor such as a bottom gate transistor. In some embodiments, the channel 112 and the source/drain contacts 140A, 140B are disposed on the first surface 154s1 of the gate dielectric layer 154, and the gate electrode layer 152 is disposed on a second surface 154s2 opposite to the first surface 154s1 of the gate dielectric layer 154. The gate electrode layer 152 may be overlapped with the source/drain contact 140A, the source/drain contact 140B and the channel 112 between the source/drain contacts 140A, 140B along the first direction D1. For example, as shown in FIG. 3H, a projection of the gate electrode layer 152 onto the underlying structure 180 is overlapped with a projection of the source/drain contact 140A onto the underlying structure 180, a projection of the source/drain contact 140B onto the underlying structure 180 and a projection of the channel 112 onto the underlying structure 180. It is noted that although widths of the source/drain contacts 140A, 140B, the channel 122 and the gate structure 150 in a third direction D3 are illustrated as being equal, the widths of the source/drain contacts 140A, 140B, the channel 122 and the gate structure 150 may be different. The third direction D3 is substantially perpendicular to the first direction D1 and the second direction D2. For example, the third direction D3 is a horizontal direction (e.g., y direction or width direction).

As shown in FIG. 3G, the source/drain contacts 140A continuously covers the first sidewall 112w1 and the first portion 112s1 of the channel 112, and the source/drain contacts 140B covers the second sidewall 112w2 and the second portion 112s2 of the channel 112. For example, a projection of the source/drain contact 140A onto the underlying structure 180 is partially overlapped with a projection of the channel 112 onto the underlying structure 180, and similarly, a projection of the source/drain contact 140B onto the underlying structure 180 is partially overlapped with a projection of the channel 112 onto the underlying structure 180. For example, the first portion 112s1 of the surface 112s is continuous with the first sidewall 112w1, and the second portion 112s2 of the surface 112s is continuous with the second sidewall 112w2. In other words, the source/drain contacts 140A continuously covers the first sidewall 112w1 and the first portion 112s1 of the channel 112, and the source/drain contacts 140B covers the second sidewall 112w2 and the second portion 112s2 of the surface 112s of the channel 112. The source/drain contacts 140A is in direct contact with the first sidewall 112w1 and the first portion 112s1 of the channel 112, and the source/drain contacts 140B is in direct contact with the second sidewall 112w2 and the second portion 112s2 of the channel 112, for example. In alternative embodiments, the sidewalls 112w1, 112w2 are also referred to as side surfaces or the like. In some embodiments, as shown in FIG. 3G, a contact length Lc of the source/drain contact 140A, 140B overlapped with the channel 112 therebelow is substantially equal to the thickness t of the lining layer 130 on the pattern 122 as shown in FIG. 3B to FIG. 3D. In other words, the contact length Lc is predetermined by the thickness t of the lining layer 130, which is formed by applying ALD process. Thus, the source/drain contact 140A, 140B may have an atomically precise control of the contact length Lc. The contact length Lc formed by applying the ALD process is smaller than the contact length formed by using the lithography process (e.g., applying an e-beam lithography alignment accuracy and photoresist resolution), and thus the contact length Lc may be also referred to as ultra-scaled contact length. In some embodiments, by a hybrid contact (e.g., top surface contact and sidewall contact) between the source/drain contact 140A, 140B and the channel 112, the current injection may be improved. Furthermore, a fermi-level pinning issue of contact between the source/drain contact 140A, 140B and the low dimensional material (e.g., 2D material of the channel 112) may be reduced.

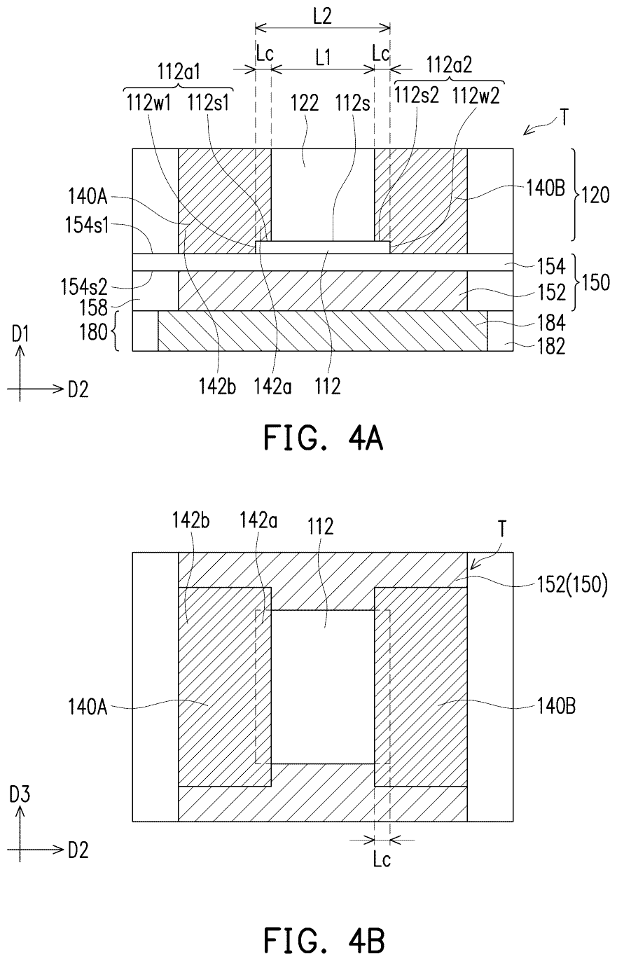

In some embodiments, a first side 142a of the source/drain contact 140A, 140B is disposed on and covers the channel 112 therebelow, and a second side 142b of the source/drain contact 140A, 140B is disposed on and covers the pattern 112′ therebelow. Thus, the source/drain contact 140A, 140B is T-shaped. In such embodiments, the source/drain contact 140A, 140B penetrates through the material layer 110 (including the channel 112 and the pattern 112′). The pattern 112′ may serve as a channel layer of another transistor (not shown) immediately adjacent to a transistor T to be formed or a dummy pattern. However, the disclosure is not limited thereto. The source/drain contact 140A, 140B may include other shape. In alternative embodiments in which the pattern 112′ is removed before forming the source/drain contact 140A or 140B, as shown in FIG. 4A and FIG. 4B, only one side 142a of the source/drain contact 140A or 140B covers the channel 112 between the source/drain contacts 140A and 140B.

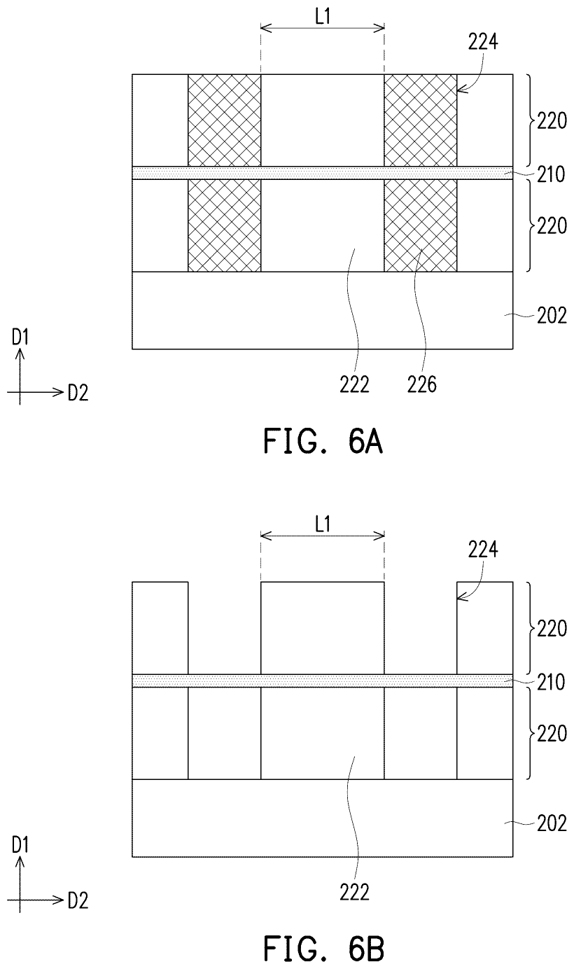

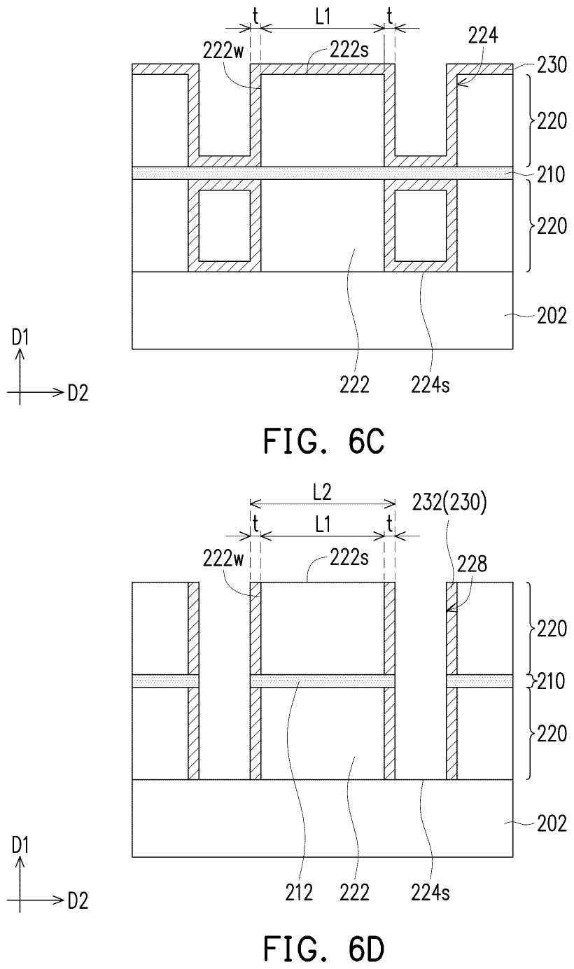

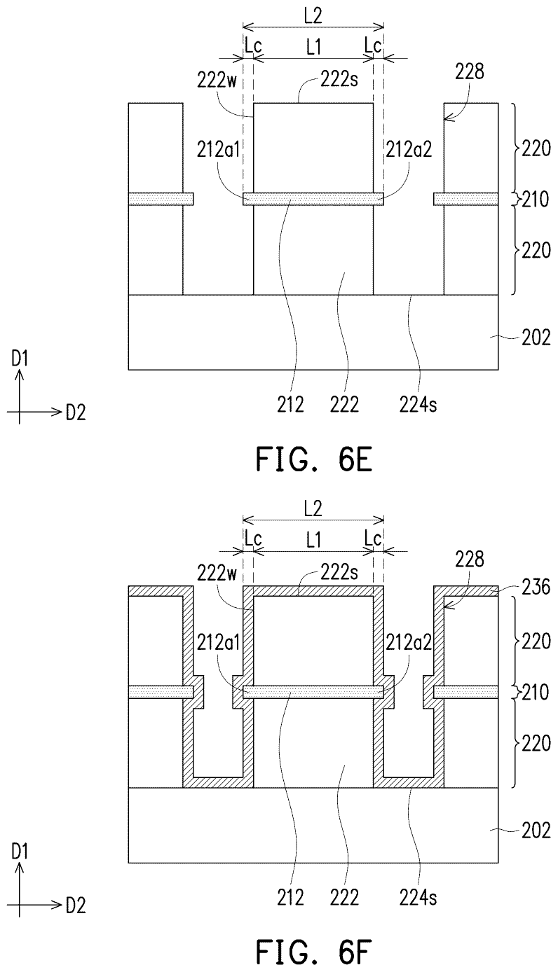

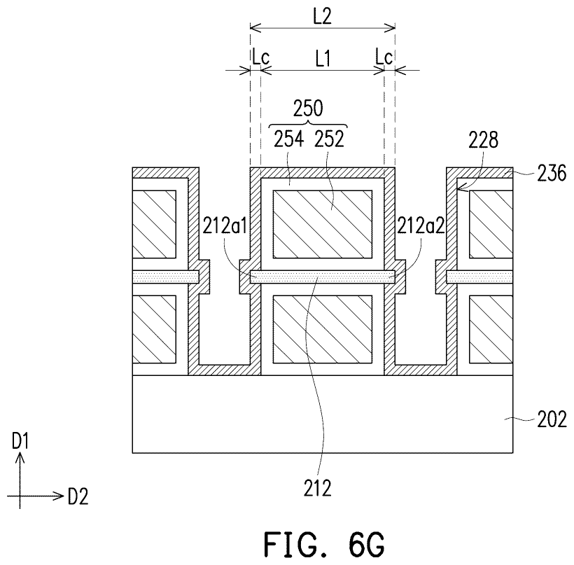

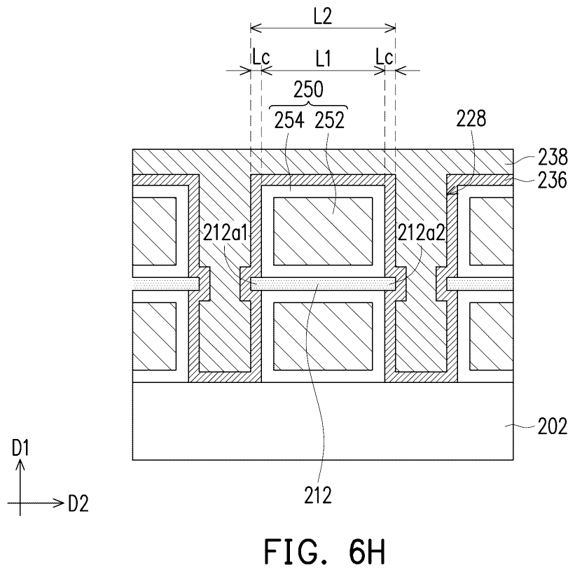

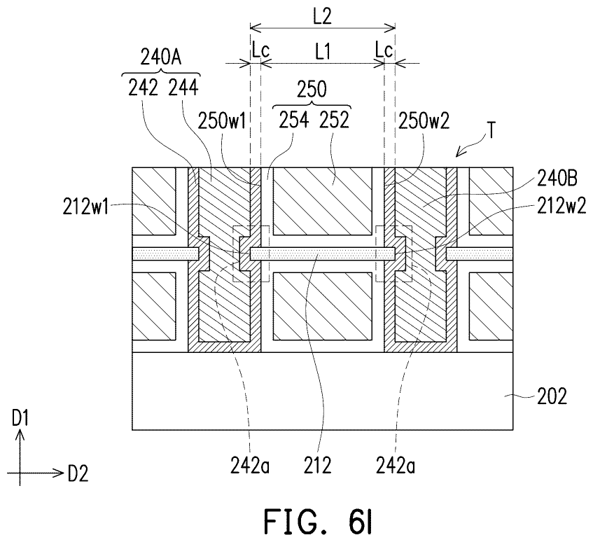

FIG. 6A to FIG. 6I are schematic cross-sectional views illustrating various stages of a method of forming a semiconductor device in accordance with some embodiments.

Referring to FIG. 6A, a material layer 210 and a plurality of patterned layers 220 on opposite sides of the material layer 210 are formed along a first direction D1. The first direction D1 is a vertical direction (e.g., z direction or height direction), for example. First, the patterned layer 220 of a first tire is formed on a substate 202, and portions of the patterned layer 220 are removed to form a plurality of patterns 222 and a plurality of openings 224 between the patterns 222. Then, a plurality of dummy patterns 226 are formed in the openings 224. After that, the material layer 210 is formed on the patterned layer 220 having the dummy patterns 226 therein. After that, the patterned layer 220 of a second tire is formed on the material layer 210, and the patterned layer 220 of the second tire has a structure similar to the patterned layer 220 of the first tire. As shown in FIG. 6A, the patterned layer 220, the material layer 210 and the patterned layer 220 are sequentially stacked on the substrate 202. The patterned layers 220 are formed on opposite sides (e.g., top and bottom sides) of the material layer 210. It is noted that for clarity, only one material layer 210 is illustrated in FIG. 6A. However, in alternative embodiments, there may be a plurality of material layers 210, and the patterned layers 220 and the material layers 210 are alternately stacked on the substrate 202. The patterned layer 220 may be also referred to as sacrificial layer, and the pattern 222 may be also referred to as sacrificial patterns.

In some embodiments, the material layer 210, the patterned layer 220 and the dummy pattern 226 may have different materials (or compositions) that may provide for different etch selectivity therebetween. In some embodiments, the patterned layer 220 may include an oxide material such as semiconductor oxide (e.g., SiO₂) or other suitable materials. The dummy pattern 226 may include a high-k dielectric material (e.g., Al₂O₃, HfO₂), metal oxide such as transition metal oxide (e.g., WOₓ, MoOₓ, TiOₓ) or the like. The substrate 202 is similar to the substrate 102, so the detailed description thereof is omitted herein. In some embodiments, the material and forming method of the material layer 210 are similar to those of the material layer 110, so the detailed description thereof is omitted herein. In some embodiments, the material layer 210 includes the 2D material such as carbon nanotubes for n-FET or TMDs (e.g., MoS₂) for p-FET. The pattern 222 may have a length L1 corresponding to a length (Lg) of the gate structure to be formed along a second direction D2. The second direction D2 is substantially perpendicular to the first direction D1. For example, the second direction D2 is a horizontal direction (e.g., x direction or length direction). The material layer 210 may be a semiconductor nanosheet and may be considered as a channel, a nanochannel or a channel region in the subsequent processes. The terms “semiconductor nanosheet,” “semiconductor nanostructure”, “channel” and “channel region” may be used interchangeably herein.

Referring to FIG. 6B, portions of the patterned layers 220 are removed, to form the openings 208 between the patterns 222. The openings 208 and the patterns 222 are both disposed at opposite sides (e.g., top and bottom sides) of the material layer 210, for example. Accordingly, the opposite sides (e.g., top and bottom sides) of first portions of the material layer 210 are exposed by the openings 208 while the opposite sides (e.g., top and bottom sides) of second portions of the material layer 210 are covered by the patterns 222.

Referring to FIG. 6C, a lining layer 230 is formed on the opposite sides of the material layer 210 exposed by the openings 224 and on sidewalls of the patterns 222. The lining layer 230 may be conformally formed on exposed surfaces of the patterned layer 220 and the material layer 210. For example, the lining layer 230 is conformally and continuously formed on top surfaces 222s and opposite sidewalls 222w of the patterns 222 and bottom surfaces 224s of the openings 224 (e.g., top surface of the substrate 202). In addition, the lining layer 230 wraps around opposite surfaces (e.g., top and bottom surfaces) of the material layer 210 exposed by the openings 224. In some embodiments, the material layer 110, the patterned layer 220 and the lining layer 230 may have different materials (or compositions) that may provide for different etch selectivity therebetween. The lining layer 230 may include an oxide material such as semiconductor oxide (e.g., SiO₂), a high-k dielectric material (e.g., Al₂O₃, HfO₂), metal oxide such as transition metal oxide (e.g., WOₓ, MoOₓ, TiOₓ) or the like. The lining layer 230 is formed by an atomic layer deposition (ALD) process or the like, for example. In some embodiments, a cycle number of the ALD process is in a range of 10 to 70. The lining layer 230 has a thickness t on the sidewall 222 w of the pattern 222 of the patterned layer 220 along the second direction D2, and the lining layer 230 also has the thickness t on the top surface 222s of the pattern 222 and on the material layer 210 along the first direction D1. The thickness t of the lining layer 230 is smaller than 10 nm.

Referring to FIG. 6D, the lining layer 230 wrapping around the material layer 210 and the portion of the material layer 210 are removed. The lining layer 230 and the material layer 210 may be partially removed by an anisotropic etch process such as anisotropic reactive ion etch (RIE) process. In some embodiments, the lining layer 230 on horizontal surfaces of the patterned layer 220 and the material layer 210 are removed. For example, the lining layer 230 on the top surface 222s of the pattern 222 and on the bottom surface of the opening 224 (e.g., top surface of the substrate 202) are removed, and the lining layer 230 wrapping around the material layer 210 are removed. During the removal process, the lining layer 230 on the sidewalls 222w of the patterns 222 are not removed or remained substantially intact. Thus, as shown in FIG. 6D, the sidewalls 222w of the patterns 222 are still covered by the lining layer 230 (e.g., lining patterns 232 of the lining layer 230). In some embodiments, after partial removal of the material layer 210, the opening 224 of the patterned layer 220 of the first tier is communicated with the opening 224 of the patterned layer 220 of the second tier, to form an opening 228.

In some embodiments, the portion of the material layer 210 wrapped around by the material layer 210 may be also removed by the same etch process, and the remained material layer 210 includes a plurality of patterns 212. In some embodiments, sidewalls of the pattern 212 are substantially flush with outer sidewalls of the lining layers 130 on the pattern 122. Accordingly, the pattern 212 may have a length L2 substantially equal to a total length of the pattern 122 and the lining layer 130 on opposite sidewalls 122w of the pattern 122, that is, the length L2 of the pattern 212 is substantially equal to L1 plus 2t (i.e., L1+2t).

Referring to FIG. 6E, the lining layer 230 on the opposite sidewalls 222w of the pattern 222 is removed, to expose the pattern 212. The lining layer 230 (e.g., lining patterns 232 of the lining layer 230) is removed by a wet etch process or a dry etch process, for example. In some embodiments, the lining layer 230 is entirely removed by a wet etch process. After removal of the lining layer 230, opposite sides 212a1, 212a2 of the pattern 212 are exposed. The sides 212a1, 212a2 (e.g., left and right sides in FIG. 6E) are disposed opposite to each other along the second direction D2. In some embodiments, the pattern 212 serves as a channel 212, and is also referred to as channel or channel region. The pattern 212 extends beyond the pattern 222 by a length Lc, and the length L2 of the pattern 212 is substantially equal to L1 plus 2Lc (i.e., L1+2Lc). The length Lc is substantially equal to the thickness t, for example.

Referring to FIG. 6F, a contact material 236 is formed on the exposed surfaces of the patterns 222 and the patterns 212. For example, the contact material 236 is conformally formed on exposed surfaces of the openings 228, that is, the top surfaces 222s and the sidewalls 222w of the patterns 222, the exposed surfaces of the channel 212 and the top surface of the substrate 202. The contact material 236 may provide a better contact/adherence to the channel 112. The contact material 236 includes, for example, TiN, TaN, TiSiN, TaSiN, WSiN, TiC, TaC, TiAlC, TaAlC, TiAlN, TaAlN, or a combination thereof. The conductive material 236 may be formed through CVD, ALD, plating, or other suitable deposition techniques.

Referring to FIG. 6G, the patterned layers 220 are replaced with gate structures 250. The patterns 222 may be entirely removed by a wet etch process or a dry etch process, to form an opening among the contact material 236 and the channel 212. Then, a gate dielectric layer 254 is formed on an exposed surface of the opening to wrap around the channel 212, and a gate conductive layer 252 is formed to fill the opening and wrap around the channel 212, for example. In some embodiments, as shown in FIG. 6G, the gate structure 250 includes the gate dielectric layer 254 and the conductive layer 252 and wraps around the channel 212.

Referring to FIG. 6H, a conductive material 238 is formed on the contact material 236 and fills the openings 228 between the patterns 212. The conductive material 238 includes, for example, cobalt, tungsten, copper, titanium, tantalum, aluminum, zirconium, hafnium, a combination thereof, or other suitable conductive materials. The conductive material 238 may be formed through CVD, ALD, plating, or other suitable deposition techniques.

Referring to FIG. 6I, source/drain contacts 140A, 140B are formed at opposite sides of the channel 212 along the second direction D2, to form a transistor T. For example, the contact material 236 and the conductive material 238 outside the openings 228 are removed. In some embodiments, the source/drain contacts 140A, 140B are disposed on opposite sides of the channel 112. The contact material 236 and the conductive material 238 may be removed by a planarization process such as CMP process, to form a contact layer 242 and a conductive layer 244 of the source/drain contacts 140A, 140B. The transistor T is a gate-all-around (GAA) transistor. The gate structure 250 may have a gate length substantially equal to the length L1 of the pattern 222 as shown in FIG. 6A to FIG. 6F.

In some embodiments, a first sidewall 212w1 of the channel 212 protrudes beyond a first sidewall 250w1 of the gate structure 250, and a second sidewall 212w2 opposite to the first sidewall 212w1 of the channel 212 protrudes beyond a second sidewall 250w2 opposite to the first sidewall 250w1 of the gate structure 250. The source/drain contact 240A (e.g., contact layer 242) is continuously disposed on the first sidewall 250w1 of the gate structure 250 and the first sidewall 212w1 of the channel 212, and the source/drain contact 240B (e.g., contact layer 242) is continuously disposed on the second sidewall 250w2 of the gate structure 250 and the second sidewall 212w2 of the channel 212, for example. The contact layer 242 may be in direct contact with the gate structure 250 and the channel 212. A surface of the source/drain contact 240A, 240B may be substantially coplanar with a surface of the gate structure 250. For example, surfaces (e.g., top surfaces) of the contact layer 242 and the conductive layer 244 of the source/drain contact 240A, 240B are substantially coplanar with a surface (e.g., top surface) of the gate dielectric layer 254 of the gate structure 250. The contact layer 242 may surround the conductive layer 244, and a surface (e.g., bottom surface) may be substantially coplanar with a surface (e.g., bottom surface) of the gate dielectric layer 254 of the gate structure 250. As shown in FIG. 6I, a portion 242a of the contact layer 242 of the source/drain contact 240A surrounds and/or wraps around a first end of the channel 212, and similarly, a portion 242a of the contact layer 242 of the source/drain contact 240B surrounds and/or wraps around a second end opposite to the first end of the channel 212. The portion 242a of the contact layer 242 is C-shaped, for example.

In some embodiments, as shown in FIG. 6I, the length Lc of the source/drain contact 240A, 240B overlapped with the channel 212 therebelow is also referred to as a contact length, and is substantially equal to the predetermined thickness t of the lining layer 130 on the pattern 222 as shown in FIG. 6C and FIG. 6D. In other words, the contact length Lc is determined by the thickness t of the lining layer 230, which is formed by applying ALD process. Thus, the source/drain contact 240A, 240B may have an atomically precise control of the contact length Lc. For example, the contact length Lc formed by applying the ALD process is smaller than the contact length formed by using the lithography process (e.g., applying an e-beam lithography alignment accuracy and photoresist resolution). In some embodiments, the contact length Lc is also referred to as ultra-scaled contact length. In some embodiments, by a C-shaped contact (e.g., top surface contact, bottom surface contact and sidewall contact) between the source/drain contact 240A, 240B and the channel 212, the current injection may be improved. Furthermore, a fermi-level pinning issue of contact between the source/drain contact 240A, 240B and the low dimensional material (e.g., 2D material of the channel 212) may be reduced.

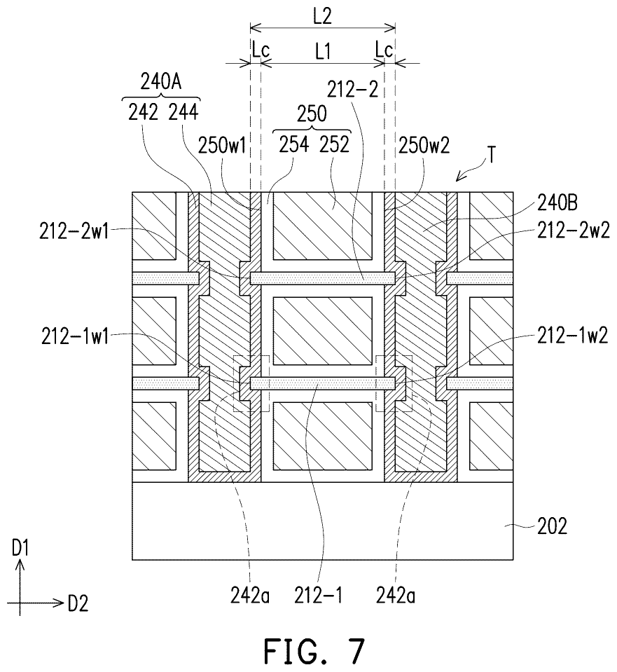

In some embodiments, only one channel layer 212 is illustrated. However, the disclosure is not limited thereto. In alternative embodiments, as shown in FIG. 7, the transistor T includes a plurality of channels (e.g., nanochannels) 212-1, 212-2 stacked along the first direction D1. The gate structure 250 continuously wraps around the channels 212-1, 212-2, and the source/drain contacts 240A, 240B are disposed at opposite sides of the channels 212-1, 212-2. In some embodiments, the first sidewall 212-1w1, 212-2w1 of each of the channels 212-1, 212-2 protrudes beyond a first sidewall 250w1 of the gate structure 250, and the second sidewall 212-1w2, 212-2w2 of each of the channels 212-1, 212-2 protrudes beyond a second sidewall 250w2 opposite to the first sidewall 250w1 of the gate structure 250. The source/drain contact 240A (e.g., contact layer 242) is continuously disposed on the first sidewall 250w1 of the gate structure 250 and the first sidewalls 212-1w1, 212-2w1 of the channels 212-1, 212-2, and the source/drain contact 240B (e.g., contact layer 242) is continuously disposed on the second sidewall 250w2 of the gate structure 250 and the second sidewalls 212-1w2, 212-2w2 of the channels 212-1, 212-2, for example. In such embodiments, as shown in FIG. 7, portions 242a of the contact layer 242 of the source/drain contact 240A respectively surround and/or wrap around first ends of the channels 212-1, 212-2, and similarly, portions 242a of the contact layer 242 of the source/drain contact 240B respectively surround and/or wrap around second ends opposite to the first ends of the channels 212-1, 212-2. Each portion 242a of the contact layer 242 is C-shaped, for example.

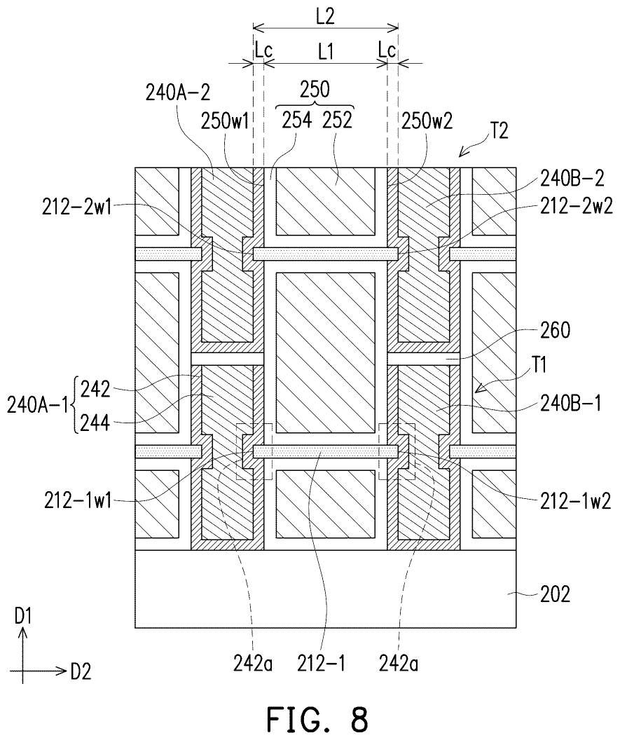

FIG. 8 is a cross-sectional view of a transistor of a semiconductor device in accordance with some alternative embodiments of the disclosure. Referring to FIG. 8, the semiconductor device is a complementary FET (CFET) device, and includes a first transistor T1 and a second transistor T2 disposed vertically above the first transistor T1. The first transistor T1 and the second transistor T2 are disposed on a substrate 202, for example. The first transistor T1 includes a channel 212-1 and source/drain contacts 240A-1, 240B-1 aside the channel 212-1, and the second transistor T2 includes a channel 212-2 and source/drain contacts 240A-2, 240B-2 aside the channel 212-2. In some embodiments, the first transistor T1 and the second transistor T2 share a gate structure 250. However, the disclosure is not limited thereto. The first transistor T1 and the second transistor T2 may include a gate structure 250 respectively. The channel 212-1 of the first transistor T1 is formed over the substrate 202, and the channel 212-2 of the second transistor T2 is formed over the channel 212-1 and vertically spaced apart from the channel 212-1. The gate structure 250 is formed to wrap around the channels 212-1, 212-2. In some embodiments, the channel 212-1 includes the 2D material such as TMDs (e.g., MoS₂) for p-FET, and the channel 212-2 includes the 2D material such as carbon nanotubes for n-FET. The source/drain contacts 240A-1, 240B-1 are formed on opposite sides of the channel 212-1, and source/drain contacts 240A-2, 240B-2 are formed on opposite sides of the channel 212-2. The source/drain contacts 240A-1, 240B-1, 240A-2, 240B-2 may include a contact layer 242 and a conductive layer 244. In some embodiments, the material and forming method of the channels 212-1, 212-2, the gate structure 250 and the source/drain contacts 240A-1, 240B-1, 240A-2, 240B-2 are similar to those of the channel 212, the gate structure 250 and the source/drain contacts 240A, 240B in FIG. 6A to FIG. 6I, so the detailed description thereof is omitted herein. An insulating layer 260 is formed between the source/drain contacts 240A-1, 240A-2 and between the source/drain contacts 240B-1, 240B-2, for example. The insulating layer 260 may include an organic material such as silicon oxycarbide or the like.

In some embodiments, a first sidewall 212-1w1, 212-2w1 of the channel 212-1, 212-2 protrudes beyond a first sidewall 250w1 of the gate structure 250, and a second sidewall 212-1w2, 212-2w2 opposite to the first sidewall 212-1w1, 212-2w1 of the channel 212-1, 212-2 protrudes beyond a second sidewall 250w2 opposite to the first sidewall 250w1 of the gate structure 250. The source/drain contact 240A-1, 240A-2 (e.g., contact layer 242) is continuously disposed on the first sidewall 250w1 of the gate structure 250 and the first sidewall 212-1w1, 212-2w1 of the channel 212-1, 212-2, and the source/drain contact 240B-1, 240B-2 (e.g., contact layer 242) is continuously disposed on the second sidewall 250w2 of the gate structure 250 and the second sidewall 212-1w2, 212-2w2 of the channel 212-1, 212-2, for example.

In some embodiments, only one channel layer 212-1 is illustrated in the first transistor T1 and only one channel layer 212-1 is illustrated in the second transistor T2, however, the disclosure is not limited thereto. In alternative embodiments, the first transistor T1 includes a plurality of channels (e.g., nanochannels) 212-1 stacked along the first direction D1, and the second transistor T2 includes a plurality of channels (e.g., nanochannels) 212-2 stacked along the first direction D1. In such embodiments (not shown), the gate structure 250 wraps around the channels 212-1, 212-2 of the first and second transistors, the source/drain contacts 240A-1, 240B-1, 240A-2, 240B-2 are respectively disposed at opposite sides of the channels 212-1, 212-2, and the insulating layer 260 is disposed between the channels 212-1 and the channels 212-2. The first transistor T1 and the second transistor T2 may be formed over the substrate 202 sequentially, for example, the channel(s) 212-1 and the channel(s) 212-2 are sequentially formed on the same substrate 202. Alternately, the first transistor T1 and the second transistor T2 may be formed on different substrates and then be bonded to each other, and one of the substrates is removed to form the CFET device. For example, the channel layer(s) 212-1 of the first transistor T1 is formed on a first substrate, and the channel layer(s) 212-2 of the second transistor T2 is formed on a second substrate, and then the first substrate and the second substrate are face to face bonded, to stack the channel layers 212-1 and 212-2.

In some embodiments, as shown in FIG. 8, portions 242a of the contact layer 242 of the source/drain contact 240A-1, 240A-2 respectively surround and/or wrap around first ends of the channels 212-1, 212-2, and similarly, portion 242a of the contact layer 242 of the source/drain contact 240B-1, 240B-2 may respectively surround and/or wrap around second ends opposite to the first ends of the channels 212-1, 212-2. The portion 242a of the contact layer 242 is C-shaped, for example.

It is noted that by using the processes described in FIG. 6A to FIG. 6E, a C-shaped contact (e.g., top surface contact, bottom surface contact and sidewall contact) between the pattern 240 and the pattern 212 is formed, and the processes may be applied in any suitable semiconductor device with the need of a reduced contact length (e.g., ultra-scaled contact length) and/or an improvement of the contact therebetween.

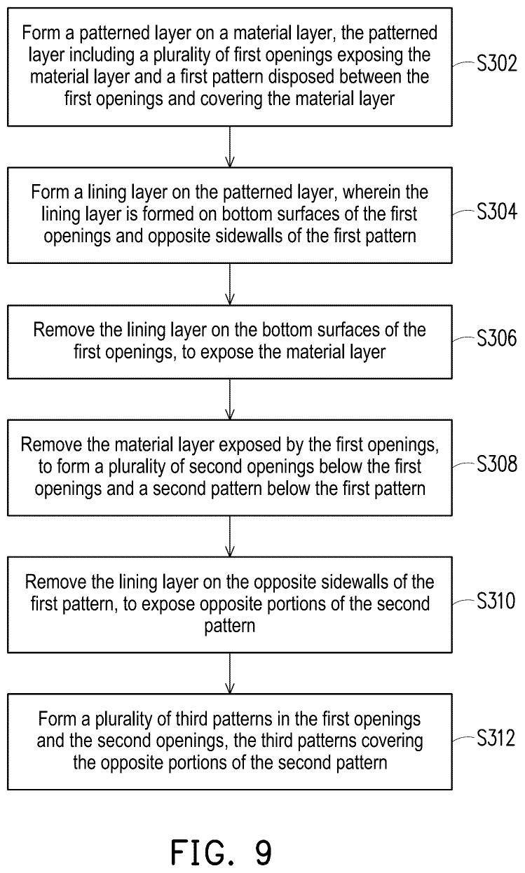

FIG. 9 illustrates a method of forming a semiconductor device in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act S302, a patterned layer is formed on a material layer, wherein the patterned layer includes a plurality of first openings exposing the material layer and a first pattern disposed between the first openings and covering the material layer. FIGS. 1A, 3A and 6B illustrate varying views corresponding to some embodiments of act S302.

At act S304, a lining layer is formed on the patterned layer, wherein the lining layer is formed on bottom surfaces of the first openings and opposite sidewalls of the first pattern. FIGS. 1B and 3B illustrate varying views corresponding to some embodiments of act S304.

At act S306, the lining layer on the bottom surfaces of the first openings is removed to expose the material layer. FIGS. 1C and 3C illustrate varying views corresponding to some embodiments of act S306.

At act S308, the material layer exposed by the first openings is removed, to form a plurality of second openings below the first openings and a second pattern below the first pattern. FIGS. 1D and 3D illustrate varying views corresponding to some embodiments of act S308.

At act S310, the lining layer on the opposite sidewalls of the first pattern is removed, to expose opposite portions of the second pattern. FIGS. 1E and 3E illustrate varying views corresponding to some embodiments of act S310.

At act S312, a plurality of third patterns are formed in the first openings and the second openings, wherein the third patterns cover the opposite portions of the second pattern. FIGS. 1F and 3G illustrate varying views corresponding to some embodiments of act S312.

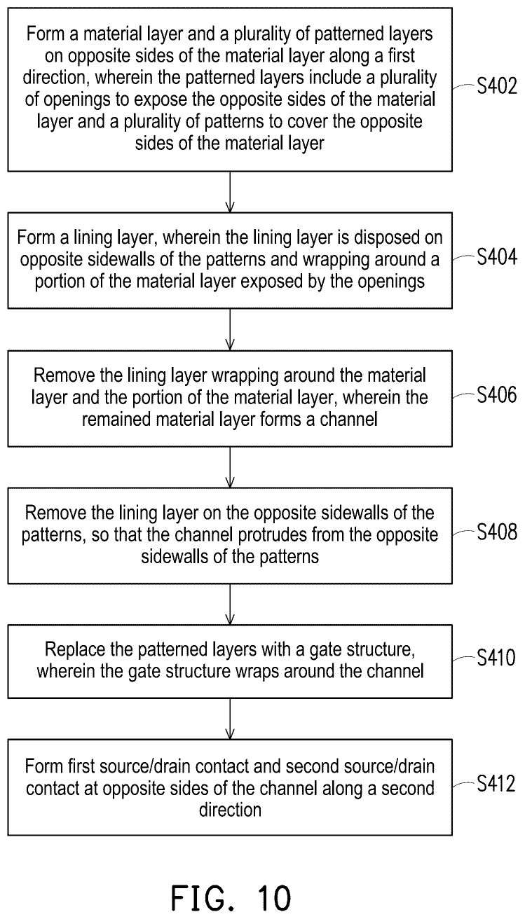

FIG. 10 illustrates a method of forming a semiconductor device in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act S402, a material layer and a plurality of patterned layers on opposite sides of the material layer are formed along a first direction, wherein the patterned layers comprise a plurality of openings to expose the opposite sides of the material layer and a plurality of patterns to cover the opposite sides of the material layer. FIG. 6B illustrates a view corresponding to some embodiments of act S402.

At act S404, a lining layer is formed, wherein the lining layer is disposed on opposite sidewalls of the patterns and wrapping around a portion of the material layer exposed by the openings. FIG. 6C illustrates a view corresponding to some embodiments of act S404.

At act S406, the lining layer wrapping around the material layer and the portion of the material layer is removed, wherein the remained material layer forms a channel. FIG. 6D illustrates a view corresponding to some embodiments of act S406.

At act S408, the lining layer on the opposite sidewalls of the patterns is removed, so that the channel protrudes from the opposite sidewalls of the patterns. FIG. 6E illustrates a view corresponding to some embodiments of act S408.

At act S410, the patterned layers are replaced with a gate structure, wherein the gate structure wraps around the channel. FIG. 6G illustrates a view corresponding to some embodiments of act S410.

At act S412, first source/drain contact and second source/drain contact are formed at opposite sides of the channel along a second direction. FIG. 6I illustrates a view corresponding to some embodiments of act S412.

In accordance with some embodiments of the disclosure, a semiconductor device includes a channel, a gate structure, a first source/drain contact, a second source/drain contact and a dielectric layer. The gate structure is disposed on the channel. The first source/drain contact covers a first sidewall and a first portion of a surface of the channel. The second source/drain contact covers a second sidewall opposite to the first sidewall and a second portion of the surface of the channel. The first source/drain contact and the second source/drain contact are disposed in the dielectric layer.

In accordance with some embodiments of the disclosure, a method of forming a semiconductor device includes following steps. A patterned layer is formed on a material layer, wherein the patterned layer includes a plurality of first openings exposing the material layer and a first pattern disposed between the first openings and covering the material layer. A lining layer is formed on the patterned layer, wherein the lining layer is formed on bottom surfaces of the first openings and opposite sidewalls of the first pattern. The lining layer on the bottom surfaces of the first openings is removed, to expose the material layer. The material layer exposed by the first openings is removed, to form a plurality of second openings below the first openings and a second pattern below the first pattern. The lining layer on the opposite sidewalls of the first pattern is removed, to expose opposite portions of the second pattern. A plurality of third patterns are formed in the first openings and the second openings, wherein the third patterns cover the opposite portions of the second pattern.

In accordance with some embodiments of the disclosure, a method of forming a semiconductor device includes following steps. A material layer and a plurality of patterned layers on opposite sides of the material layer are formed along a first direction, wherein the patterned layers comprise a plurality of openings to expose the opposite sides of the material layer and a plurality of patterns to cover the opposite sides of the material layer. A lining layer is formed, wherein the lining layer is disposed on opposite sidewalls of the patterns and wrapping around a portion of the material layer exposed by the openings. The lining layer wrapping around the material layer and the portion of the material layer is removed, wherein the remained material layer forms a channel. The lining layer on the opposite sidewalls of the patterns is removed, so that the channel protrudes from the opposite sidewalls of the patterns. The patterned layers are replaced with a gate structure, wherein the gate structure wraps around the channel. First source/drain contact and second source/drain contact are formed at opposite sides of the channel along a second direction.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a channel;
a gate structure, disposed on the channel;
a first source/drain contact, covering a first sidewall and a first portion of a surface of the channel;
a second source/drain contact, covering a second sidewall opposite to the first sidewall and a second portion of the surface of the channel; and
a dielectric layer, wherein the first source/drain contact and the second source/drain contact are disposed in the dielectric layer.

2. The semiconductor device of claim 1, further comprising a substrate, wherein the gate structure, the channel, the first source/drain contact and the second source/drain contact are disposed on the substrate, and the channel is disposed between the substrate and the gate structure.

3. The semiconductor device of claim 2, wherein the gate structure comprises a gate electrode layer, a gate dielectric layer between the gate electrode layer and the channel and a spacer surrounding the gate electrode layer.

4. The semiconductor device of claim 1, wherein the gate structure is disposed on a first side of the channel along a first direction, and the first source/drain contact and the second source/drain contact are disposed on a second side opposite to the first side of the channel along the first direction.

5. The semiconductor device of claim 4, wherein the gate structure is overlapped with the first source/drain contact, the second source/drain contact and the channel along the first direction.

6. The semiconductor device of claim 1, wherein the first source/drain contact is in contact with the first sidewall and the first portion of the surface of the channel, and the second source/drain contact is in contact with the second sidewall and the second portion of the surface of the channel.

7. The semiconductor device of claim 1, wherein the channel comprises a two-dimensional material.

8. The semiconductor device of claim 1, wherein the gate structure wraps around the channel.

9. The semiconductor device of claim 8, wherein the first sidewall of the channel protrudes beyond a first sidewall of the gate structure, and the second sidewall of the channel protrudes beyond a second sidewall opposite to the first sidewall of the gate structure.

10. The semiconductor device of claim 9, wherein the first source/drain contact is continuously disposed on the first sidewall of the gate structure and the first sidewall of the channel, and the second source/drain contact is continuously disposed on the second sidewall of the gate structure and the second sidewall of the channel.

11. The semiconductor device of claim 8, wherein the channel comprises a plurality of stacked nanochannels.

12. A method of forming a semiconductor device, comprising:
forming a patterned layer on a material layer, the patterned layer comprising a plurality of first openings exposing the material layer and a first pattern disposed between the first openings and covering the material layer;
forming a lining layer on the patterned layer, wherein the lining layer is formed on bottom surfaces of the first openings and opposite sidewalls of the first pattern;
removing the lining layer on the bottom surfaces of the first openings, to expose the material layer;
removing the material layer exposed by the first openings, to form a plurality of second openings below the first openings and a second pattern below the first pattern;
removing the lining layer on the opposite sidewalls of the first pattern, to expose opposite portions of the second pattern; and
forming a plurality of third patterns in the first openings and the second openings, the third patterns covering the opposite portions of the second pattern.

13. The method of claim 12, wherein the lining layer is formed by an ALD process
14. The method of claim 12, wherein removing the lining layer on the bottom surfaces of the first openings is performed by using an anisotropic etch process.

15. The method of claim 12, further comprising removing the patterned layer after forming the third patterns.

16. A method of forming a semiconductor device, comprising:
forming a material layer and a plurality of patterned layers on opposite sides of the material layer along a first direction, wherein the patterned layers comprise a plurality of openings to expose the opposite sides of the material layer and a plurality of patterns to cover the opposite sides of the material layer;
forming a lining layer, wherein the lining layer is disposed on opposite sidewalls of the patterns and wrapping around a portion of the material layer exposed by the openings;
removing the lining layer wrapping around the material layer and the portion of the material layer, wherein the remained material layer forms a channel;
removing the lining layer on the opposite sidewalls of the patterns, so that the channel protrudes from the opposite sidewalls of the patterns;
replacing the patterned layers with a gate structure, wherein the gate structure wraps around the channel; and
forming first source/drain contact and second source/drain contact at opposite sides of the channel along a second direction.

17. The method of claim 16, wherein the lining layer is formed by an ALD process
18. The method of claim 16, wherein forming the first source/drain contact and the second source/drain contact comprises:
forming a contact material on exposed surfaces of the gate structure and the channel; and
forming a conductive material on the contact material; and
removing portions of the contact material and the conductive material, to form contact layers and conductive layers of the first source/drain contact and the second source/drain contact.

19. The method of claim 18, wherein the contact layer of the first source/drain contact is continuously formed on a first sidewall of the channel and a first sidewall of the gate structure, and the contact layer of the second source/drain contact is continuously formed on a second sidewall opposite to the first sidewall of the channel and a second sidewall opposite to the first sidewall of the gate structure.

20. The method of claim 18, wherein replacing the patterned layers with the gate structure comprises:
after forming the contact material, removing the patterned layers to form a second opening; and
before forming the conductive material, forming the gate structure in the second opening to wrap around the channel.
